(19) United States
(12) Patent Application Publication
(10) Pub. No.: US 2015/0221870 A1
(43) Pub. Date: Aug. 6, 2015

(54) METHOD FOR PRODUCING EL DISPLAY DEVICE, TRANSFER SUBSTRATE USED IN PRODUCTION OF EL DISPLAY DEVICE, AND METHOD FOR PRODUCING TRANSFER SUBSTRATE USED IN PRODUCTION OF EL DISPLAY DEVICE

(71) Applicant: JOLED INC., Chiyoda-ku, Tokyo (JP)

(72) Inventors: Yoichi Shintani, Osaka (JP); Ryuichi Murai, Osaka (JP); Toshiyuki Akiyama, Osaka (JP); Akinobu Iwamoto, Tokyo (JP)

(73) Assignee: JOLED INC., Tokyo (JP)

(21) Appl. No.: 14/428,787

(22) PCT Filed: Apr. 16, 2013
(86) PCT No.: PCT/JP2013/002553

§ 371 Date: Mar. 17, 2015

(30) Foreign Application Priority Data
Sep. 25, 2012 (JP) 2012-210821

(51) Int. Cl. H01L 51/00; H01L 27/32

(52) U.S. Cl. CPC H01L 51/0013; H01L 51/0005; H01L 27/3246; H01L 27/3248; H01L 27/3211

(57) ABSTRACT

A method for manufacturing an EL display device, the EL display device including: a light-emitter emitting light of at least red, green, and blue colors; and a thin-film transistor array device controlling light-emission of the light-emitter, the light-emitter including at least red, green, and blue light-emitting layers arranged within regions partitioned by banks, and being sealed with a sealing layer, the method including: preparing at least three types of transfer substrates corresponding to red, green, and blue colors, each transfer substrate having a supporting substrate on which a transfer layer including at least red, green, or blue light-emitting material is formed by an inkjet method; and when forming the light-emitting layers, repeatedly performing a transfer process that includes transferring the transfer layer onto a transfer-target substrate of the EL display device by using the transfer substrate.

### TECHNICAL FIELD

The present disclosure relates to a method for manufacturing an EL display device, a transfer substrate used in manufacturing an EL display device, and a method for manufacturing a transfer substrate used in manufacturing an EL display device.

### BACKGROUND ART

In recent years, much effort has been made in development of next-generation display devices. In particular, EL (Electroluminescence) display devices is now being given attention, in which a first electrode, a plurality of organic layers including a light-emitting layer, and a second electrode are stacked in the stated order on a substrate for driving. EL display devices are self-luminous. Accordingly, EL display devices have a wide viewing angle. In addition, EL display devices do not require a backlight. Therefore, EL display devices are capable of driving with reduced power, are highly responsive, and have a reduced thickness. Due to these features, there is a strong demand for application of EL display devices to large-screen display devices such as TVs.

There are various methods for forming light-emitting layers of such an EL display device. One example of the methods is patterning R-, G-, and B-color light-emitting layers by vapor deposition or application of light-emitting materials onto a substrate.

Another example is a transfer method using a radiant ray of laser light for example, as disclosed in Patent Literature 1. Transfer method is a method of transferring a transfer layer to a transfer-target substrate for forming an EL light-emitting element. The transfer layer includes a light-emitting material and is formed on a transfer substrate. Specifically, first, a transfer substrate is formed, which includes a supporting member and a transfer layer formed thereon. Next, the transfer substrate is disposed to face the transfer-target substrate. Finally, the transfer substrate is irradiated with a radiant ray under a reduced pressure environment. Consequently, the transfer layer is transferred to the transfer-target substrate, and the light-emitting layers are formed on the transfer-target substrate.

### CITATION LIST

### Patent Literature

[Patent Literature 1] Japanese Patent Application Publication No. 2009-146715

### SUMMARY OF INVENTION

The present disclosure provides an EL display device manufacturing method that realizes high-definition EL display devices, a transfer substrate used in manufacturing an EL display device, and a method of manufacturing a transfer substrate used in manufacturing an EL display device.

To achieve this aim, the present disclosure provides a method for manufacturing an EL display device, the EL display device including: a light-emitter that emits light of at least red, green, and blue colors; and a thin-film transistor array device that controls light-emission of the light-emitter, the light-emitter including at least red, green, and blue light-emitting layers arranged within regions partitioned by banks, and being sealed with a sealing layer, the method including: preparing at least three types of transfer substrates corresponding to red, green, and blue colors, each transfer substrate having a supporting substrate on which a transfer layer including at least one of red, green, and blue light-emitting materials is formed by an inkjet method; and when forming the light-emitting layers, repeatedly performing a transfer process that includes transferring the corresponding transfer layer onto a transfer-target substrate of the EL display device by using the corresponding transfer substrate.

The present disclosure also provides a transfer substrate used in manufacturing an EL display device, including: a substrate; a plurality of photothermal conversion layers arranged with an interval therebetween on the substrate and generating heat when absorbing laser light; a plurality of barrier walls disposed to provide openings in regions that exist in the normal directions of the plurality of photothermal conversion layers; and a transfer layer formed by, using an inkjet method, ejecting light emitting material into the openings defined by the plurality of barrier walls, wherein the plurality of photothermal conversion layers are not disposed in regions that exist in the normal directions of regions other than the regions in which the openings are provided or regions in which the barrier walls are disposed.

The present disclosure also provides a method for manufacturing a transfer substrate used in manufacturing an EL display device, including: preparing a transfer substrate not undergoing transfer layer formation, including: a substrate; a plurality of photothermal conversion layers arranged on the substrate with an interval therebetween and generating heat when absorbing laser light; and a plurality of barrier walls disposed to provide openings in regions that exist in the normal directions of the plurality of photothermal conversion layers, the plurality of photothermal conversion layers being not disposed in regions that exist in the normal directions of regions other than the regions in which the openings are provided or regions in which the barrier walls are disposed; and forming a transfer layer on the transfer substrate not undergoing transfer layer formation, by, using an inkjet method, ejecting light-emitting material into the openings defined by the plurality of barrier walls.

The present disclosure thus provides an EL display device manufacturing method that allows for higher definition EL display devices, a transfer substrate used in manufacturing an EL display device, and a method of manufacturing a transfer substrate used in manufacturing an EL display device.

### BRIEF DESCRIPTION OF DRAWINGS

FIG. 1 is a perspective view of an EL display device pertaining to an embodiment of the present disclosure.

FIG. 2 is an electrical circuit diagram showing a circuit configuration of a pixel circuit.

FIG. 3 is a cross-sectional view showing a cross-sectional configuration of R, G, and B pixels in the EL display device.

FIG. 4 is a process chart showing manufacturing processes according to an embodiment of the EL display device manufacturing method pertaining to the present disclosure.

FIG. 5A is a chart showing a part of the process of manufacturing an R-color transfer substrate having an R-color transfer layer for forming an R-color light-emitting layer.

FIG. 5B is a chart showing a part of the process of manufacturing an R-color transfer substrate having an R-color transfer layer for forming an R-color light-emitting layer.

FIG. 5C is a chart showing a part of the process of manufacturing an R-color transfer substrate having an R-color transfer layer for forming an R-color light-emitting layer.

FIG. 5D is a chart showing a part of the process of manufacturing an R-color transfer substrate having an R-color transfer layer for forming an R-color light-emitting layer.

FIG. 5E is a chart showing a part of the process of manufacturing an R-color transfer substrate having an R-color transfer layer for forming an R-color light-emitting layer.

FIG. 6A illustrates the outline of a light-emitting layer forming processes A5 included in the manufacturing method pertaining to the present disclosure, by which R-, G-, and B-color light-emitting layers are formed.

FIG. 6B illustrates the outline of the light-emitting layer forming processes A5 included in the manufacturing method pertaining to the present disclosure, by which R-, G-, and B-color light-emitting layers are formed.

FIG. 6C illustrates the outline of the light-emitting layer forming processes A5 included in the manufacturing method pertaining to the present disclosure, by which R-, G-, and B-color light-emitting layers are formed.

### DESCRIPTION OF EMBODIMENTS

The following describes an embodiment in detail, with reference to the drawings when necessary. In some cases, however, details more than needs may be omitted. For example, details of well-known issues or redundant explanation of substantially same configurations may be omitted. This is for the purpose of avoiding redundancy more than needs and facilitating understanding by a person having an ordinary skill in the art.

Note that the inventor(s) provide the accompanying drawings and the following explanation in order to help a person skilled in the art understand the present disclosure sufficiently well, and do not intend to thereby limit the subject matters recited in the claims.

### Embodiment 1

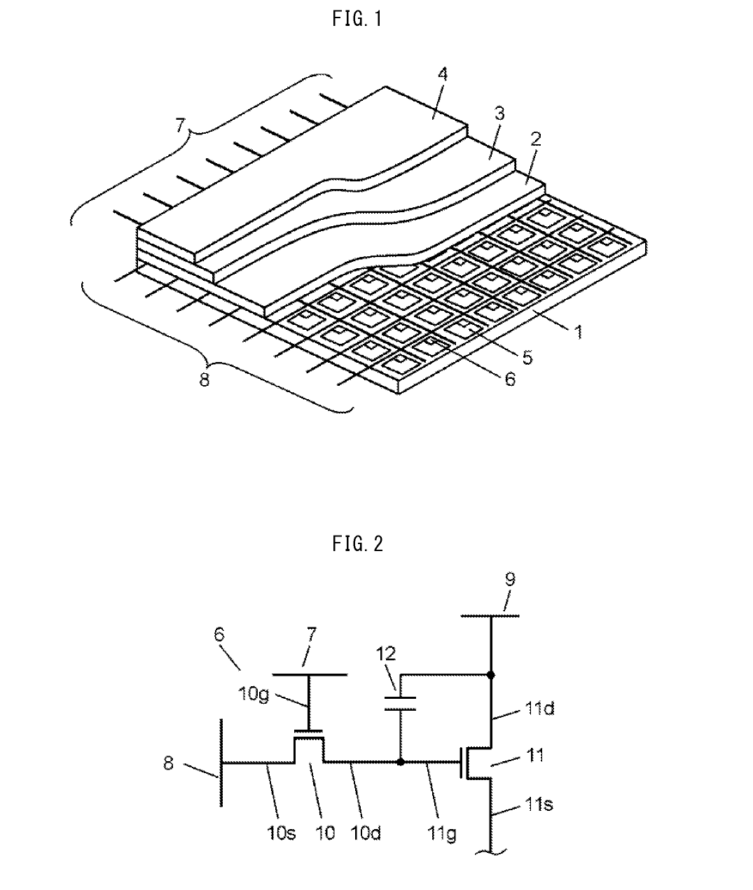

The following describes an EL display device manufacturing method, a transfer substrate used in manufacturing an EL display device, and a method of manufacturing a transfer substrate used in manufacturing an EL display device, with reference to FIGS. 1 through 6C.

FIG. 1 is a perspective view schematically showing the configuration of an EL display device. FIG. 2 shows a circuit configuration of a pixel circuit that drives pixels.

As shown in FIG. 1 and FIG. 2, the EL display device includes, from bottom to top, a thin-film transistor array device 1, an anode 2, and a light-emitter including a light-emitting layer 3 and a cathode 4. The thin-film transistor array device 1 has a plurality of thin-film transistors arranged thereon. The anode 2 serves as a lower electrode. The light-emitting layer 3 is made up from organic material. The cathode 4 serves as an upper electrode. Light-emission of the light-emitter is controlled by the thin-film transistor array device 1. In the light-emitter, the light-emitting layer 3 is interposed between the anode 2 and the cathode 4 which constitute an electrode pair. A hole transport layer is formed between the anode 2 and the light-emitting layer 3. An electron transport layer is formed between the light-emitting layer 3 and the cathode 4 which is light-transmissive. The thin-film transistor array device 1 has a plurality of pixels 5 arranged in a matrix thereon.

Each pixel 5 is driven by a pixel circuit 6 provided therefor. The thin-film transistor array device 1 includes a plurality of gate lines 7, a plurality of source lines 8 serving as signal lines, and a plurality of power supply lines 9 (omitted from FIG. 1). The plurality of gate lines 7 are arranged on the thin-film transistor array 1 in columns. The plurality of source lines 8 are arranged in rows so as to intersect with the gate lines 7. The plurality of power supply lines 9 extend in parallel with the source lines 8.

Each column of the gate lines 7 is connected to a gate electrode 10g of a thin-film transistor 10. The thin-film transistor 10 operates as a switching element in each pixel circuit 6. Each row of the source lines 8 is connected to a source electrode 10s of the thin-film transistor 10. Each row of the power supply lines 9 is connected to a drain electrode 11d of a thin-film transistor 11. The thin-film transistor 11 operates as a driving element in each pixel circuit 6.

As shown in FIG. 2, the pixel circuit 6 includes the thin-film transistor 10, the thin-film transistor 11, and a capacitor 12. The capacitor 12 stores data to be displayed on the corresponding pixel.

The thin-film transistor 10 includes the gate electrode 10g, the source electrode 10s, the drain electrode 10d, and a semiconductor film (omitted from the drawing). The drain electrode 10d is connected to the capacitor 12 and the gate electrode 11g of the thin-film transistor 11. The thin-film transistor 10, when voltage is applied to the gate line 7 and the source line 8 connected thereto, stores into the capacitor 12 the value of the voltage applied to the source line 8.

The thin-film transistor 11 includes the gate electrode 11g, the source electrode 11s, the drain electrode 11d, and a semiconductor film (omitted from the drawing). The drain electrode 11d is connected to the power supply line 9 and the capacitor 12. The source electrode 11s is connected to the anode 2. The thin-film transistor 11 supplies the anode 2 with current corresponding to the voltage value stored in the capacitor 12, from the power supply line 9 via the source electrode 11s. In other words, the EL display device having the above-described configuration is an active matrix device in which display control is performed for each of the pixels 5 located at the intersections of the gate lines 7 and the source lines 8.

In the EL display device, the light-emitter is formed such that a plurality of pixels, each having at least one of red (R), green (G), and blue (B) light-emitting layers, are arranged in a matrix. Hence the light-emitter emits light of at least red, green, and blue colors. The pixels are separated from each other by banks. The banks are made up from protrusions extending in parallel with the gate lines 7 and protrusions extending in parallel with the source lines 8, which intersect with each other. A pixel having one of R-, G-, and B-color light-emitting layers is formed in each area surrounded by the protrusions, i.e., in each opening defined by the banks.

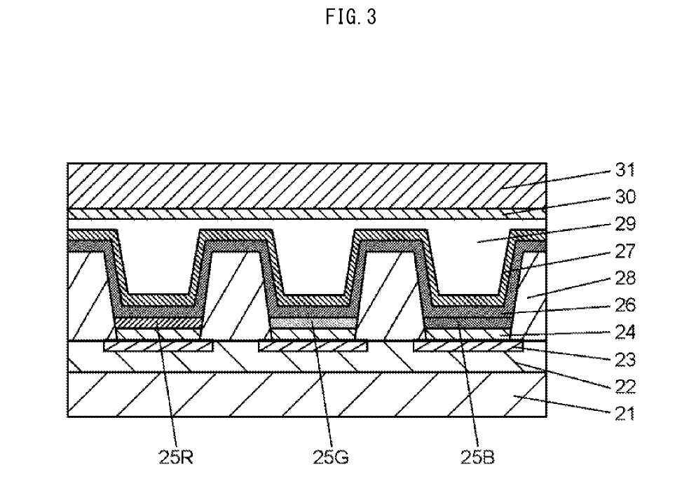

FIG. 3 is a cross-sectional view showing a cross-sectional configuration of the R-, G-, and B-color pixels in the EL display device. As shown in FIG. 3, in EL display device, a thin-film transistor array device 22 is formed on a base substrate 21. The base substrate 21 is formed from a glass substrate, a flexible resin substrate, or the like. The thin-film transistor array device 22 is included in the above-described pixel circuit 6. An anode 23, which serves as a lower electrode, is formed on the thin-film transistor array device 22 with a planarizing insulation film (omitted from the drawing) therebetween. A hole transport layer 24, a light-emitting layers 25R, 25G, and 25B, which are made from organic material, an electron transport layer 26, and a cathode 27, which serves as a light-transmissive upper electrode, are stacked on the anode 23 in the stated order. An RGB light-emitter is configured in this way. The light-emitting layers 25R, 25G, and 25B are formed in areas partitioned by banks 28 which serve as insulation layers.

The light-emitter having such a configuration is coated with a sealing layer 29 of silicon nitride, for example. The light-emitter coated with the sealing layer 29 is sealed by bonding a sealing substrate 31 onto the entire surface of the sealing layer 29 with an adhesive layer 30 therebetween. The sealing substrate 31 is formed from a light-transmissive glass substrate, a flexible resin substrate, or the like.

Here, the banks 28 ensure insulation between the anode 23 and the cathode 27. Also, the banks 28 partition the light-emitting area in a predetermined pattern. The banks 28 are formed from silicon oxide or photosensitive resin such as polyimide.

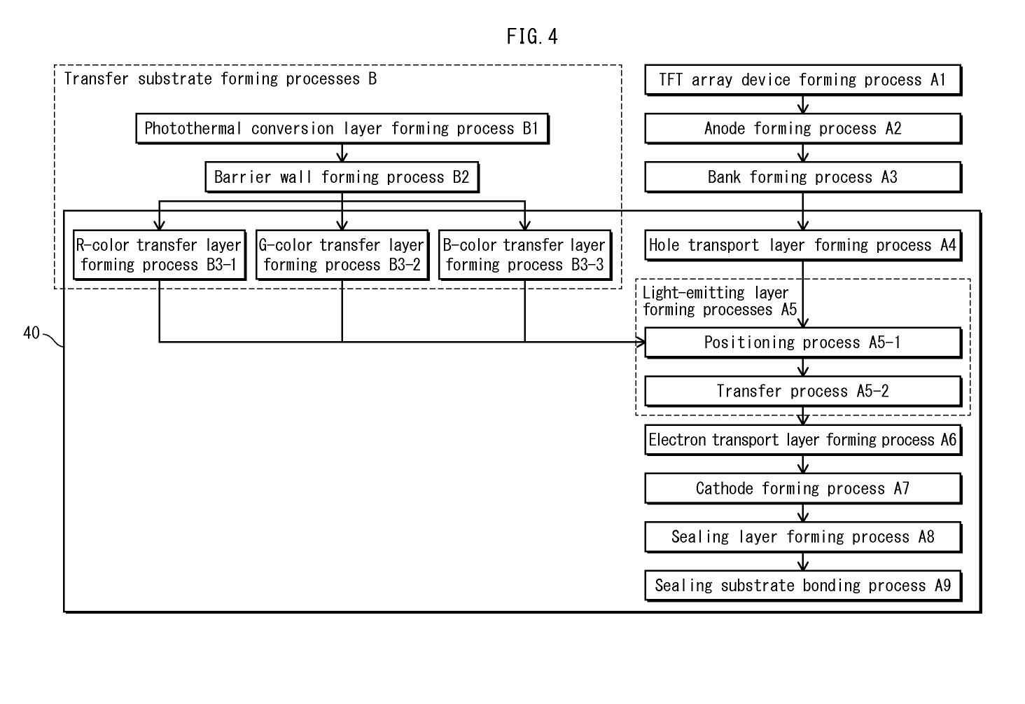

Next, a description is given to an EL display device manufacturing method pertaining to the present disclosure, with reference to FIG. 4 to FIG. 6C.

According to the EL display device manufacturing method pertaining to the present disclosure, three types of transfer substrates corresponding to R, G, and B colors are prepared. Each of these transfer substrates is formed by coating a supporting substrate with a transfer layer, which includes R-, G-, or B-color light-emitting material, by application of an inkjet method. Using these R-, G-, and B-color transfer substrates one by one, the transfer layer on each transfer substrate is transferred to the transfer-target substrate of the EL display device. Thus, the light-emitting layers are formed on the transfer-target substrate. Such a transfer process of transferring a transfer layer onto a transfer-target substrate is performed by using the R-, G- and B-color transfer substrates one by one. Note that the light-emitting layers are not limited to of the three types, R, G and B. Depending on the form of the EL display device, the light-emitting layers may be formed from light-emitting material of other than R, G or B. If this is the case, a plurality of types of transfer substrates are prepared corresponding to the types of the light-emitting layer. The transfer process of transferring the transfer layers onto the transfer-target substrates may be performed by using such transfer substrates.

FIG. 4 is a process chart showing manufacturing processes according to one embodiment of the EL display device manufacturing method pertaining to the present disclosure.

In FIG. 4, isolation atmosphere 40 is an atmosphere for preventing exposure to the air. The isolation atmosphere 40 is formed by reduction of the pressure, or introduction of a dry gas or an inert gas. A plurality of manufacturing apparatuses for performing the manufacturing processes are connected via a transport apparatus that transports materials between the manufacturing apparatuses. Via the transport apparatus, some of the manufacturing processes are connected to storage equipment for storing the materials. The manufacturing apparatuses, the transport apparatus, and the storage equipment have a space within which the isolation atmosphere 40 is formed. The manufacturing apparatuses, the transport apparatus, and the storage equipment are connected via the isolation atmosphere 40. The materials are assembled, transported, and stored within the isolation atmosphere 40 formed within the space, so that the materials are prevented from being exposed directly to the air. This is because the materials could be degraded when exposed to moisture, oxygen, etc. The isolation atmosphere 40 is formed by reducing the pressure within the apparatuses or the equipment by evacuation using a vacuum pump, or by introducing a dry gas or an inert gas. Thus the isolation atmosphere 40 is formed within the apparatuses or the equipment. According to another method, the isolation atmosphere 40 may be formed individually within each of the manufacturing apparatuses, the transport apparatus, and the storage equipment. If this is the case, the manufacturing apparatuses, the transport apparatuses, and the storage equipment are not connected via the isolation atmosphere 40. Even in this case, the manufacturing apparatuses and the transport apparatus need to be connected via the isolation atmosphere 40 when transporting materials from the manufacturing apparatuses to the transport apparatus. Similarly, the transport apparatus and the storage equipment are connected via the isolation atmosphere 40 when transporting the materials from the transport apparatus to the storage equipment. Thus the materials are prevented from being exposed directly to the air. Even in this case, the isolation atmosphere 40 is formed within the apparatuses or the equipment by reducing the pressure within the apparatuses or the equipment, or by introducing a dry gas or an inert gas.

Next, a description is given to the manufacturing method pertaining to the present technology, with reference to the chart shown in FIG. 4.

First, a TFT array device forming process A1 is performed. In the TFT array device forming process A1, a thin-film transistor array device 22 constituting the pixel circuit 6 is formed on the base substrate 21.

In the TFT array device forming process A1, the following processing is performed. First, a predetermined thin film of metal material, semiconductor material, or the like is formed by a thin-film formation method such as vacuum deposition or sputtering. The thin film is patterned by photolithography so as to have a predetermined pattern. Next, constituent components such as the plurality of gate lines 7, the plurality of source lines 8, the plurality of power supply lines 9, the plurality of thin-film transistors 10 and 11, the plurality of capacitors 12, and so on are layered thereon via an interlayer insulation layer therebetween. The series of processing described so far is performed in the TFT array device forming process A1.

After the TFT array device forming process A1 is performed, an anode forming process A2 is performed. In the anode forming process A2, the anode 23 is formed on the thin-film transistor array device 22 with a planarizing insulation film therebetween. The anode 23 is connected to the source electrode 11s of the thin-film transistor 11 of the thin-film transistor array device 22. The anode 23 is one of the two electrodes of the light emitter.

In the anode forming process A2, a photosensitive resin is applied to the entire surface of thin-film transistor array device 22. Thus the planarizing insulation film is formed on the thin-film transistor array device 22. The planarizing insulation film is patterned into a predetermined configuration by exposure to light and development. Thus a connection hole, for connection to the source electrode 11s, of the thin-film transistor 11 is formed on the thin-film transistor array device 22, which is to be baked. Subsequently, a film of the material of the anode is formed by sputtering, for example. Then, the anode material film thus formed is etched to have a predetermined configuration. Thus, the anode 23 is formed on the thin-film transistor array device 22. The series of processing described so far is performed in the anode forming process A2.

Subsequently, in a bank forming process A3, photosensitive resin is applied to the entire surface of the base substrate 21 so as to cover the anode 23. After that, an opening is provided by photolithography, in the position corresponding to the light-emitting region of the anode 23, thereby forming the banks 28.

After that, the base substrate 21 with the banks 28 thus formed is transported to the isolation atmosphere 40 described above.

After the base substrate 21 with the banks 28 thus formed is transported to the isolation atmosphere 40, the hole transport layers 24 are sequentially formed in the hole transport layer forming process A4, for example by vapor deposition using an area mask. Thus the substrate not undergoing formation of the light-emitting layers is formed.

Upon formation of the substrate not undergoing formation of the light-emitting layers, the substrate thus formed is transported within the isolation atmosphere 40. Then, a light-emitting layer forming processes A5 are performed. In the light-emitting layer forming processes A5, the light-emitting layers 25R, 25G, and 25B are formed in between the banks 28. The light-emitting layer forming processes A5 are described later in detail.

After the light-emitting layer forming processes A5 are performed, the substrate with the light-emitting layers 25R, 25G, and 25B thus formed is transported within the isolation atmosphere 40. An electron transport layer forming process A6 is performed on the substrate thus transported. In the electron transport layer forming process A6, the electron transport layers 26 is formed by vapor deposition within the isolation atmosphere 40. After the electron transport layer 26 is formed, the substrate is transported within the isolation atmosphere 40. Then, a cathode forming process A7 is performed on the substrate thus transported. In the cathode forming process A7, the cathode 27 is formed by vapor deposition within the isolation atmosphere 40.

After the light-emitter is thus formed, the substrate is transported within the isolation atmosphere 40. Then, a sealing layer forming process A8 is performed on the substrate thus transported. In the sealing layer forming process A8, the entire light-emitter is covered with the sealing layer 29 by vapor deposition or CVD. The sealing layer 29 is formed from silicon nitride or the like.

After that, a sealing substrate bonding process A9 is performed within the isolation atmosphere 40 on the substrate with the sealing layer 29 thus formed. In the sealing substrate bonding process A9, the sealing substrate 31 is bonded to the entire surface of the sealing layer 29 with the adhesive layer 30 therebetween. The sealing substrate 31 is formed from a light-transmissive glass substrate, a flexible resin substrate, or the like. When the sealing substrate 31 has a color filter formed thereon, the sealing substrate 31 is bonded to the sealing layer 29 with the adhesive layer 30 therebetween so that the surface of the sealing substrate 31 on which the color filter is formed faces the sealing layer 29.

In the sealing layer forming step A8, when the entire light-emitter can be completely sealed with the sealing layer 29, it is not essential to perform the sealing substrate bonding process A9 within the isolation atmosphere 40. If this is the case, the sealing substrate bonding process A9 may be performed outside the isolation atmosphere 40.

Furthermore, when the entire light-emitter can be completely sealed with the sealing layer 29, it is not essential to bond the sealing substrate 31 to the sealing layer 29. Furthermore, when the entire light-emitter can be completely sealed with the sealing substrate 31, it is not essential to cover the light-emitter with the sealing layer 29. In short, any method may be used insofar as the entire light-emitter can be sealed.

The EL display device is manufactured by performing the above-described processes.

Next, a description is given to the process of forming the light-emitting layers of the EL display device. According to an EL display device manufacturing method pertaining to the present disclosure, the light-emitting layers are formed on the transfer-target substrate of the EL display device by the following method. First, at least three types of transfer substrates corresponding to the R, G, and B colors are prepared. Each of these transfer substrates is formed by coating a supporting substrate with a transfer layer, which includes R, G, or B light-emitting material, by application of an inkjet method. Using these R-, G-, and B-color transfer substrates one by one, the transfer layer on each transfer substrate is transferred to the transfer-target substrate of the EL display device. Thus, the light-emitting layers are formed on the transfer-target substrate. Such a transfer process of transferring the transfer layer onto the transfer-target substrate is performed by using the R-, G-, and B-color transfer substrates one by one.

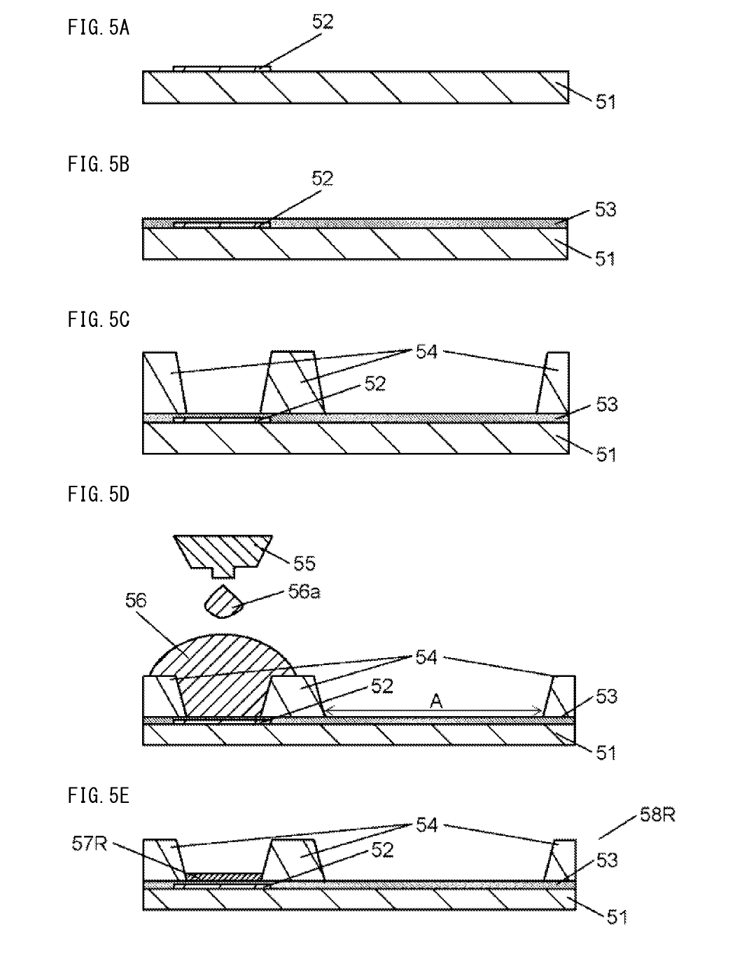

First, a description is given to a transfer substrate manufacturing method, with reference to FIGS. 5A through 5E.

FIGS. 5A through 5E are charts each showing a part of the process of manufacturing the R-color transfer substrate having the R-color transfer layer for forming the R-color light-emitting layer. Although not explained below, the G-color transfer substrate having the G-color transfer layer for forming the G-color light-emitting layer, and the B-color transfer substrate having the B-color transfer layer for forming the B-color light-emitting layer can be manufactured through a similar process.

First, as shown in FIG. 5A, a plurality of photothermal conversion layers 52 corresponding to the R pixel pattern of the EL display device are formed on the supporting substrate 51. The supporting substrate 51 is a glass substrate or a resin substrate having a high transmittance with respect to laser light. The photothermal conversion layers 52 generate heat when absorbing laser light. As shown in FIG. 5B, after the photothermal conversion layers 52 are formed, a planarizing layer 53 is formed so as to cover the photothermal conversion layers 52. The photothermal conversion layers 52 are made from metal material having a high level of laser light absorption, such as molybdenum (Mo), titanium (Ti), chromium (Cr), or an alloy containing them. The planarizing layer 53 is made from silicon nitride, silicon oxide, or the like.

Next, as shown in FIG. 5C, the barrier walls 54 are formed on the supporting substrate 51 so as to provide openings above the photothermal conversion layers 52 in correspondence with the R pixel pattern. The height of the barrier walls 54 is approximately 1 μm to 3 μm. The barrier walls 54 have been formed by application of photosensitive resin, have been shaped into a predetermined configuration by photolithography, and have been baked. The transfer substrate not undergoing formation of the transfer layer is completed at this stage.

In the case of the G-color transfer substrate and the B-color transfer substrate, their respective photothermal conversion layers 52 and the barrier walls 54 are formed to correspond to the G-color pixel pattern and the B-color pixel pattern.

Next, as shown in FIG. 5D, organic material ink 56 containing light-emitting material is applied to between the barrier walls 54 on the photothermal conversion layer 52 by an ink application apparatus 55 using an inkjet method. The ink application apparatus 55 using an inkjet method controls the amount and number of droplets 56a of the organic material ink 56 ejected from the nozzle. Thus, as shown in FIG. 5D, the organic material ink 56 is applied so as to bulge out of the opening of the barrier walls 54.

Next, the organic material ink 56 applied to bulge out of the opening of the barrier walls 54 as shown in FIG. 5D is heated and dried, so that the solvent contained in the organic material ink 56 is removed. Consequently, as shown in FIG. 5E, a transfer layer 57R containing the R light-emitting material is formed in between the barrier walls 54 on the photothermal conversion layer 52. An R-color transfer substrate 58R is thus formed.

The R-color transfer substrate 58R thus formed has, as shown in FIG. 5E, the supporting substrate 51, the plurality of photothermal conversion layers 52, the plurality of barrier walls 54, and the transfer layer 57R. The photothermal conversion layers 52 are arranged on the supporting substrate 51 with an interval therebetween. The photothermal conversion layers 52 generate heat when absorbing laser light. The barrier walls 54 are disposed so as to provide openings in regions that exist in the normal directions of the photothermal conversion layers 52. The transfer layer 57R is formed by, using an inkjet method, ejecting light emitting material into the openings defined by the plurality of barrier walls 54. The photothermal conversion layers 52 are not disposed in the regions that exist in the normal directions of regions other than the regions in which the openings are provided or the regions in which the barrier walls 54 are disposed.

Note that, in the present embodiment, the planarizing layer 53 having a flat surface is formed so as to cover the plurality of photothermal conversion layers 52. However, the planarizing layer 53 is not essential. In the case of not forming the planarizing layer 53, the barrier walls 54 may be formed directly on the supporting substrate 51 on which the plurality of photothermal conversion layers 52 have been formed, without the planarizing layer 53 therebetween. According to this configuration, the transfer layer 57R is formed directly on the photothermal conversion layers 52. Consequently, heat generated by the photothermal conversion layers 52 is most efficiently conducted to the transfer layer 57R.

Note that steps similar to the above-described steps for manufacturing the R-color transfer substrate 58R are applicable to the G-color transfer substrate 58G having a transfer layer 57G for forming a G-color light-emitting layer, and to the B-color transfer substrate 58B having a transfer layer 57B for forming a B-color light-emitting layer.

During the transfer substrate forming processes B as shown in FIG. 4, the processes from the photothermal conversion layer forming process B1 shown in FIG. 5A to the barrier wall forming process B2 shown in FIG. 5C are performed outside the isolation atmosphere 40. The R-color transfer layer forming process B3-1, the G-color transfer layer forming process B3-2, and the B-color transfer layer forming process B3-3 shown in FIGS. 5D and 5E, which are for forming the transfer layers 57R, 57G, and 57B of the R-color transfer substrate 58R, the G-color transfer substrate 580, and the B-color transfer substrate 58B respectively, are performed within the isolation atmosphere 40. The transfer substrates, on which the transfer layers are formed, are stored as they are in the isolation atmosphere 40. The transfer substrates on which the transfer layers are formed are then used in the light-emitting layer forming processes A5, which are performed within the isolation atmosphere 40.

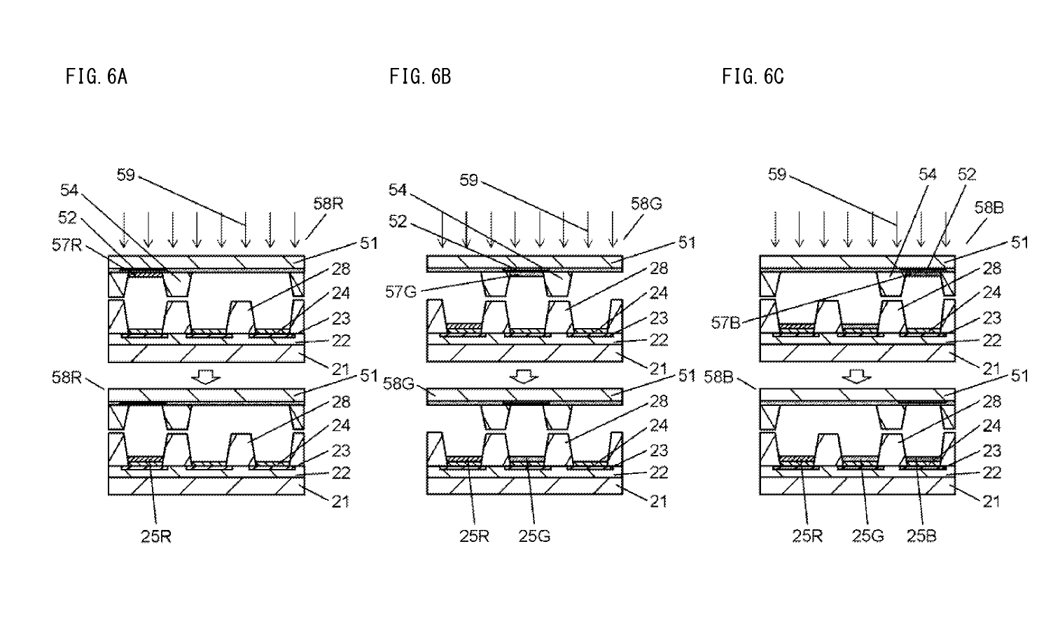

FIGS. 6A, 6B and 6C illustrate the outline of the light-emitting layer forming processes A5 included in the manufacturing method pertaining to the present disclosure, by which the R-, G-, and B-color light-emitting layers are formed. FIG. 6A illustrates formation of the R-color light-emitting layer 25R. FIG. 6B illustrates formation of the G-color light-emitting layer 25G. FIG. 6C illustrates formation of the B-color light-emitting layer 25B.

As shown in FIG. 4, the hole transport layers 24 are sequentially formed in the hole transport layer forming process A4. After the transfer-target substrate not undergoing formation of the light-emitting layers is manufactured, when performing the light-emitting layer forming processes A5, which are to be performed within the isolation atmosphere 40, the positioning process A5-1 is performed as shown in FIG. 6A, by which the R-color transfer substrate 58R is put in position relative to the transfer-target substrate not undergoing formation of the light-emitting layers. After that, in the transfer process A5-2, the R-color transfer substrate 58R is irradiated with laser light 59 from the direction of the supporting substrate 51 thereof. The laser light 59 is converted to heat by the photothermal conversion layer 52. The transfer layer 57R formed on the R-color transfer substrate 58R is sublimated or evaporated. The transfer layer 57R thus sublimated or evaporated is transferred to the insides of the banks 28 of the transfer-target substrate of the EL display device, thereby forming the R-color light-emitting layer 25R.

After that, the R-color transfer substrate 58R is removed. Then, as shown in FIG. 6B, the positioning process A5-1 is performed, by which the G-color transfer substrate 58G is put in position. After that, in the transfer process A5-2, the transfer substrate 58G is irradiated with the laser light 59 from the direction of the supporting substrate 51 thereof. Thus the transfer layer 57G of the transfer substrate 58G is sublimated or evaporated. The transfer layer 57G thus sublimated or evaporated is transferred to the insides of the banks 28 of the transfer-target substrate of the EL display device, thereby forming the G-color light-emitting layer 25G.

After that, the G-color transfer substrate 58G is removed. As shown in FIG. 6C, the positioning process A5-1 is performed, by which the B-color transfer substrate 58B is put in position. After that, in the transfer process A5-2, the transfer substrate 58B is irradiated with the laser light 59 from the direction of the supporting substrate 51 thereof. Thus the transfer layer 57B of the transfer substrate 58B is sublimated or evaporated. The transfer layer 57B thus sublimated or evaporated is transferred to the insides of the banks 28 of the transfer-target substrate of the EL display device, thereby forming the B-color light-emitting layer 25B.

Through these processes, the R-, G-, and B-color light-emitting layers 25R, 25G, and 25B are formed in the EL display device.

In the light-emitting layer forming processes A5, when transferring the transfer layers 57R, 57G, and 57B from the R-color transfer substrate 58R, the G-color transfer substrate 58G, and the B-color transfer substrate 58B by irradiating them with laser light, a laser light protection mask may be placed on the surface of each of the R-color transfer substrate 58R, the G-color transfer substrate 58G, and the B-color transfer substrate 58B, the surface being on the side of the supporting substrate 51 thereof. Such a mask allows for efficient irradiation of the corresponding photothermal conversion layer 52 with laser light.

As described above, the EL display device manufacturing method pertaining to the present disclosure is a method by which the transfer process is repeatedly performed. The EL display device includes a light-emitter and a thin-film transistor array device. The light-emitter emits light of at least red, green, and blue colors. The light-emitter includes at least red, green, and blue light-emitting layers arranged within regions partitioned by banks, and is sealed with a sealing layer. The thin-film transistor array device controls light-emission of the light-emitter. In the transfer process, at least three types of transfer substrates corresponding to red, green, and blue colors are prepared. Each transfer substrate has a supporting substrate on which a transfer layer including at least red, green, or blue light-emitting material is formed by an inkjet method. In the transfer process, each light-emitting layer is formed by transferring the corresponding transfer layer onto the transfer-target substrate of the EL display device by using each transfer substrate.

As described above, an inkjet method is used in the present disclosure, which is suitable for manufacturing a large-screen EL display device. In addition, at least three types of transfer substrates corresponding to red, green, and blue colors are prepared individually. The light-emitting layers are formed by repeatedly performing the transfer process using each of the transfer substrate, by which the transfer layers are transferred to the transfer-target substrate of the EL display device. Therefore, when realizing a high-definition device by using an inkjet method, adjacent light-emitting layers of different colors are unlikely to mix with each other. Consequently, the present disclosure can realize a high-definition EL display device.

As described for the embodiment above, each of at least three types of transfer substrates corresponding to red, green, and blue colors is formed by forming a plurality of photothermal conversion layers that correspond to a red, green, or blue pixel pattern and that generate heat when absorbing laser light, forming barrier walls defining an opening above each of the photothermal conversion layers, and then applying organic material ink with respect to the opening by an inkjet method. Furthermore, the transfer process is a process of positioning the corresponding transfer substrate relative to the transfer-target substrate of the EL display device, and then irradiating the corresponding transfer substrate with laser light from the direction of the supporting substrate so as to sublimate or evaporate the corresponding transfer layer, thereby forming the corresponding light-emitting layer in between the banks. In the EL display device manufacturing method pertaining to the present disclosure, the transfer process is repeatedly performed to transfer at least red, green, and blue light-emitting layers one by one.

Consequently, the present disclosure allows for easily realizing a high-definition EL display device by using an inkjet method which is suitable for manufacturing a large-screen EL display device.

Also, as described for the embodiment above, the transfer substrate includes a substrate, a plurality of photothermal conversion layers, a plurality of harrier walls, and a transfer layer. The plurality of photothermal conversion layers are arranged with an interval therebetween on the substrate. The photothermal conversion layers generate heat when absorbing laser light. The barrier walls are disposed so as to provide openings in regions that exist in the normal directions of the photothermal conversion layers. The transfer layer is formed by, using an inkjet method, ejecting light emitting material into the openings defined by the plurality of barrier walls. The photothermal conversion layers are not disposed in the regions that exist in the normal directions of regions other than the regions in which the openings are provided or the regions in which the barrier walls are disposed.

As described above, in the process of manufacturing the transfer substrate, the transfer layer is formed by ejecting the light-emitting material into the openings by an inkjet method. It is difficult to control the nozzle so as to always eject an appropriate amount of light-emitting material that fits the opening. In some cases, the light-emitting material ejected from the nozzle might overflow to the A region shown in FIG. 5D. Note that the A region is a region other than the regions in which the openings are provided or regions in which the barrier walls are disposed.

Suppose that the photothermal conversion layer is provided in a region below the A region. Note that the region below the A region is an example of the regions that exist in the normal direction of the A region. If this is the case, when the transfer layer is transferred to the transfer-target substrate of the EL display device, the light-emitting material overflown to the A region is sublimated or evaporated. The light-emitting material thus sublimated or evaporated can be transferred to an unintended region on the transfer-target substrate.

According to the transfer substrate pertaining to the present embodiment, however, no photothermal conversion layer is disposed below the regions other than the regions in which the openings are provided or the regions in which the barrier walls are disposed. Suppose that the light-emitting material overflows to a region such as the A region. Then, suppose that the transfer layer is transferred to the transfer-target substrate of the EL display device by using the transfer substrate in which the light-emitting material has overflown to a region such as the A region. Even in such a case, the light-emitting material overflown to the A region is unlikely to sublimate or evaporate. Consequently, the light-emitting material overflown to the region such as the A region is prevented from being transferred to an unintended region on the transfer-target substrate.

Furthermore, as described for the embodiment above, in the method of manufacturing a transfer substrate, a transfer substrate not undergoing transfer layer formation is prepared. The transfer substrate not undergoing transfer layer formation includes a substrate, a plurality of photothermal conversion layers, and a plurality of barrier walls. The plurality of photothermal conversion layers are arranged with an interval therebetween on the substrate. The photothermal conversion layers generate heat when absorbing laser light. The barrier walls are disposed so as to provide openings in regions that exist in the normal directions of the photothermal conversion layers. The photothermal conversion layers are not disposed in the regions that exist in the normal directions of regions other than the regions in which the openings are provided or the regions in which the barrier walls are disposed. In the method of manufacturing the transfer substrate, the transfer layer is formed on the transfer substrate not undergoing transfer layer formation by, using an inkjet method, ejecting light-emitting material into the openings defined by the plurality of barrier walls.

Consequently, the present disclosure allows for easily realizing a transfer substrate used in manufacturing of a high-definition EL display device by using an inkjet method which is suitable for manufacturing a large-screen EL display device.

The embodiment above is described to show an example of the technology pertaining to the present disclosure. The accompanying drawings and the detailed description are provided for this purpose.

Therefore, the constituent components appearing in the accompanying drawings or the detailed description may include constituent components that are not essential for solving the problem as well as constituent components that are essential for solving the problem. Accordingly, note that the constituent components appearing in the accompanying drawings or the detailed description should not be considered as being essential based only on the fact that they appear in the accompanying drawings or the detailed description.

Furthermore, since the embodiment above is an example of the technology pertaining to the present disclosure, the embodiment may be variously modified by replacement, addition, omission, etc., within the scope of CLAIMS or a scope equivalent thereto.

### INDUSTRIAL APPLICABILITY

As described above, the technology pertaining to the present disclosure is useful for easily realizing a high-definition EL display device.

### REFERENCE SIGNS LIST

1, 22 Thin-film transistor array device
2, 23 Anode
3 Light-emitting layer
4, 27 Cathode
5 Pixel
6 Pixel circuit
7 Gate line
8 Source line
9 Power supply line
10, 11 Thin-film transistor
21 Base substrate
24 Hole transport layer
25R, 25G, 25B Light-emitting layer
26 Electron transport layer
28 Bank
29 Sealing layer
30 Adhesive layer
31 Sealing substrate
40 Isolation atmosphere
51 Supporting substrate
52 Photothermal conversion layer
53 Planarizing layer
54 Barrier wall
55 Ink application apparatus
56 Organic material ink
56a Droplet
57R, 57G, 57B Transfer layer
58R, 58G, 58B Transfer substrate

1. A method for manufacturing an EL display device, the EL display device comprising: a light-emitter that emits light of at least red, green, and blue colors; and a thin-film transistor array device that controls light-emission of the light-emitter, the light-emitter including at least red, green, and blue light-emitting layers arranged within regions partitioned by banks, and being sealed with a sealing layer, the method comprising:
preparing at least three types of transfer substrates corresponding to red, green, and blue colors, each transfer substrate having a supporting substrate on which a transfer layer including at least one of red, green, and blue light-emitting materials is formed by an inkjet method; and
when forming the light-emitting layers, repeatedly performing a transfer process that comprises transferring the corresponding transfer layer onto a transfer-target substrate of the EL display device by using the corresponding transfer substrate.

2. The method of claim 1, wherein
each of the transfer substrates corresponding to red, green, and blue colors is formed by forming a plurality of photothermal conversion layers that correspond to a red, green, or blue pixel pattern and that generate heat when absorbing laser light, forming barrier walls defining an opening above each of the photothermal conversion layers, and then applying organic material ink with respect to the opening by an inkjet method, and
the transfer process comprises positioning the corresponding transfer substrate relative to the transfer-target substrate of the EL display device, and then irradiating the corresponding transfer substrate with laser light from the direction of the supporting substrate to sublimate or evaporate the corresponding transfer layer, thereby forming the corresponding light-emitting layer in between the banks, the transfer process being repeatedly performed to transfer the red, green, and blue light-emitting layers one by one.

3. A transfer substrate used in manufacturing an EL display device, comprising:
a substrate;
a plurality of photothermal conversion layers arranged with an interval therebetween on the substrate and generating heat when absorbing laser light;
a plurality of barrier walls disposed to provide openings in regions that exist in the normal directions of the plurality of photothermal conversion layers; and
a transfer layer formed by, using an inkjet method, ejecting light emitting material into the openings defined by the plurality of barrier walls, wherein
the plurality of photothermal conversion layers are not disposed in regions that exist in the normal directions of regions other than the regions in which the openings are provided or regions in which the barrier walls are disposed.

4. The transfer substrate of claim 3, wherein
the light-emitting material is one of red, green, and blue light-emitting materials.

5. A method for manufacturing a transfer substrate used in manufacturing an EL display device, comprising:
preparing a transfer substrate not undergoing transfer layer formation, comprising: a substrate; a plurality of photothermal conversion layers arranged on the substrate with an interval therebetween and generating heat when absorbing laser light; and a plurality of barrier walls disposed to provide openings in regions that exist in the normal directions of the plurality of photothermal conversion layers, the plurality of photothermal conversion layers being not disposed in regions that exist in the normal directions of regions other than the regions in which the openings are provided or regions in which the barrier walls are disposed; and
forming a transfer layer on the transfer substrate not undergoing transfer layer formation, by, using an inkjet method, ejecting light-emitting material into the openings defined by the plurality of barrier walls.

6. The method of claim 5, wherein
the transfer layer is formed on the transfer substrate not undergoing transfer layer formation by, using an inkjet method, ejecting one of light-emitting materials of red, green, and blue colors into the openings defined by the plurality of barrier walls.
